(19) United States
(12) Patent Application Publication
(10) Pub. No.: US 2024/0321773 A1
(43) Pub. Date: Sep. 26, 2024

(54) SEMICONDUCTOR DEVICE AND HIGH FREQUENCY SWITCH

(71) Applicants: Kabushiki Kaisha Toshiba, Tokyo (JP); Toshiba Electronic Devices & Storage Corporation, Tokyo (JP)

(72) Inventors: Kazuya NISHIHORI, Shibuya Tokyo (JP); Keita MASUDA, Kawasaki Kanagawa (JP); Takahiro NAKAGAWA, Kawasaki Kanagawa (JP); Akihiro IMADA, Yokohama Kanagawa (JP)

(21) Appl. No.: 18/367,881

(22) Filed: Sep. 13, 2023

(30) Foreign Application Priority Data
Mar. 24, 2023 (JP) 2023-048621

(51) Int. Cl. H01L 23/00; H01L 23/58; H01L 27/12

(52) U.S. Cl. CPC H01L 23/562; H01L 23/585; H01L 27/1203

(57) ABSTRACT

According to the present embodiment, a semiconductor device includes a semiconductor substrate, a circuit element, a first wiring layer, and an element protection member. The circuit element is formed on an upper surface side of the semiconductor substrate and includes at least one switching element. The first wiring layer includes a plurality of first wires electrically connected to the circuit element and is provided above the semiconductor substrate via a first interlayer dielectric film. The element protection member extends along an upper surface of the semiconductor substrate to discontinuously surround the circuit element with a conductive member. A first wire insulation film between the first wires in the first wiring layer is formed by an oxide insulation film with a dielectric constant of 3.5 or more.

### CROSS-REFERENCE TO RELATED APPLICATIONS

This application is based upon and claims the benefit of priority from the prior Japanese Patent Application No. 2023-048621, filed on Mar. 24, 2023 the entire contents of which are incorporated herein by reference.

### FIELD

Embodiments of the present invention relate to a semiconductor device and a high frequency switch.

### BACKGROUND

A semiconductor device including a circuit element has a laminated structure of plugs and wires that are electrically connected to the circuit element. Further, since the semiconductor device may be damaged by, for example, a wafer piece generated by mechanical shock at the time of dicing of a semiconductor wafer with the semiconductor device formed thereon, a chip ring (for example, a via ring, a crack stopper, a metal ring, or a metal fence) is formed around the semiconductor device in general, in order to prevent the semiconductor device being damaged by the mechanical shock. However, capacitive coupling between the chip ring and the circuit element may be increased.

### BRIEF DESCRIPTION OF THE DRAWINGS

FIG. 1 is a plan view of a semiconductor device according to the present embodiment;

FIG. 2 is a cross-sectional view taken along a line A-A in FIG. 1;

FIG. 3 is a schematic diagram illustrating a chip ring taken along a cross-section C-C in FIG. 2 in a three-dimensional manner;

FIG. 4 is a cross-sectional view illustrating a detailed configuration example of a Cu multilayer wiring structure;

FIG. 5 is a diagram schematically illustrating capacitive coupling between the chip ring and a circuit element;

FIG. 6A is a diagram illustrating an example of the chip ring having a double structure in a three-dimensional manner;

FIG. 6B is a schematic diagram illustrating two types of integrated structures in the chip ring in a three-dimensional manner;

FIG. 6C is a schematic diagram illustrating a structure in the chip ring in a three-dimensional manner;

FIG. 7A is a cross-sectional view of an example of the chip ring formed in a fourth wiring layer;

FIG. 7B is a schematic diagram illustrating a structure in the chip ring in a three-dimensional manner;

FIG. 8 is a plan view illustrating a configuration example of a semiconductor device according to a second embodiment;

FIG. 9 is a diagram illustrating a detailed configuration example of a first element region;

FIG. 10 is a diagram illustrating a network in off capacitance;

FIG. 11 is a cross-sectional view of a switching element at a level of a first-layer wire and lower levels;

FIG. 12 is a diagram illustrating a Cu multilayer wiring structure of the switching element in a three-dimensional manner;

FIG. 13 is a diagram illustrating a Cu multilayer wiring structure in the first element region in a three-dimensional manner;

FIG. 14 is a plan view of a semiconductor device according to a comparative example;

FIG. 15 is a diagram illustrating a typical configuration example of the arrangement of an FSG film;

FIG. 16 is a table representing off capacitance of the comparative example and off capacitance of the present embodiment;

FIG. 17 is a table representing off capacitance of the comparative example and off capacitance of the present embodiment;

FIG. 18 is a plan view of a semiconductor device according to a third embodiment;

FIG. 19 is a plan view illustrating a part of the semiconductor device according to the third embodiment; and

FIG. 20 is a diagram illustrating integrated structures in the chip ring in FIG. 19 in a three-dimensional manner.

### DETAILED DESCRIPTION

According to the present embodiment, a semiconductor device includes a semiconductor substrate, a circuit element, a first wiring layer, and an element protection member. The circuit element is formed on an upper surface side of the semiconductor substrate and includes at least one switching element. The first wiring layer includes a plurality of first wires electrically connected to the circuit element and is provided above the semiconductor substrate via a first interlayer dielectric film. The element protection member extends along an upper surface of the semiconductor substrate to discontinuously surround the circuit element with a conductive member. A first wire insulation film between the first wires in the first wiring layer is formed by an oxide insulation film with a dielectric constant of 3.5 or more.

Embodiments of the present invention will be explained with reference to the accompanying drawings. While characteristic configurations and operations of a semiconductor device and a high frequency switch are mainly explained in the following embodiments, the semiconductor device and the high frequency switch may include configurations and operations omitted from the following explanations.

### First Embodiment

Embodiments of the present invention will be explained below with reference to the accompanying drawings. The drawings are schematic and conceptual. The relation between the thickness and the width of each part, the ratio of size among the parts, and the like do not necessarily match those of actual products. Even in a case where the same parts are represented, the dimensions and the ratios thereof are represented differently depending on the drawings in some cases. In the specification of the present application and the respective drawings, the same elements as those already explained are denoted by like reference characters and detailed explanations thereof are omitted as appropriate.

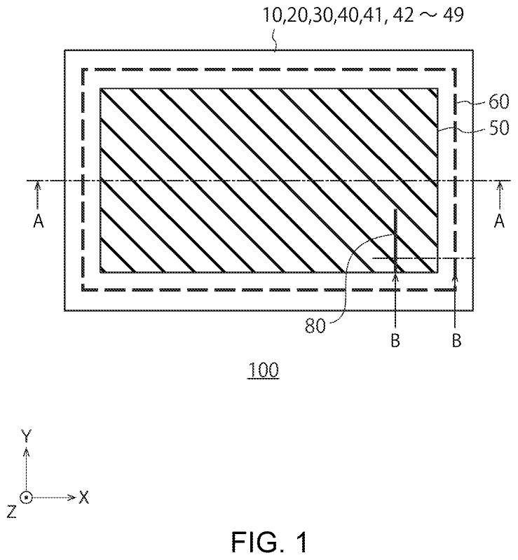

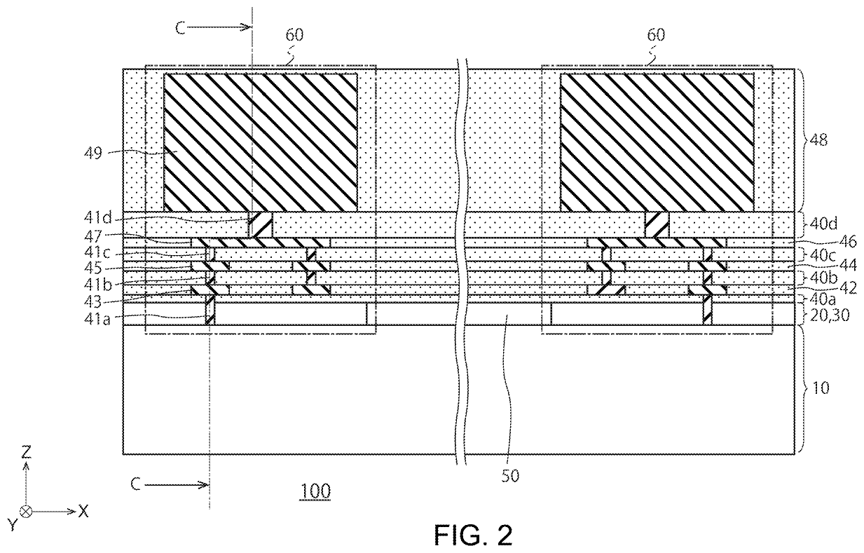

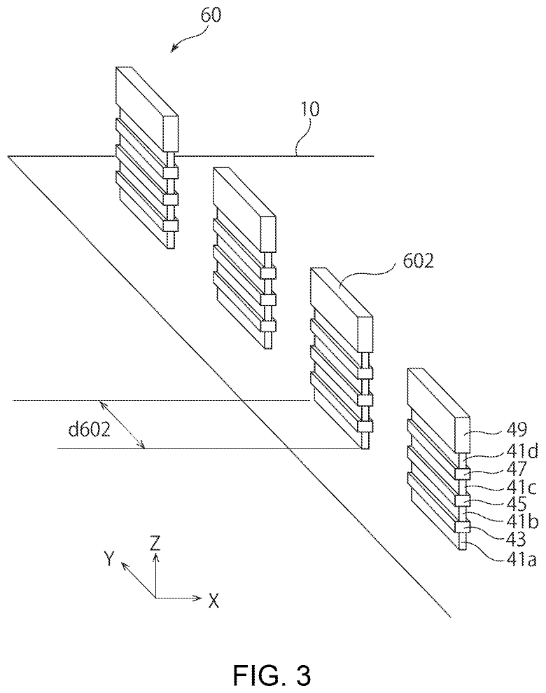

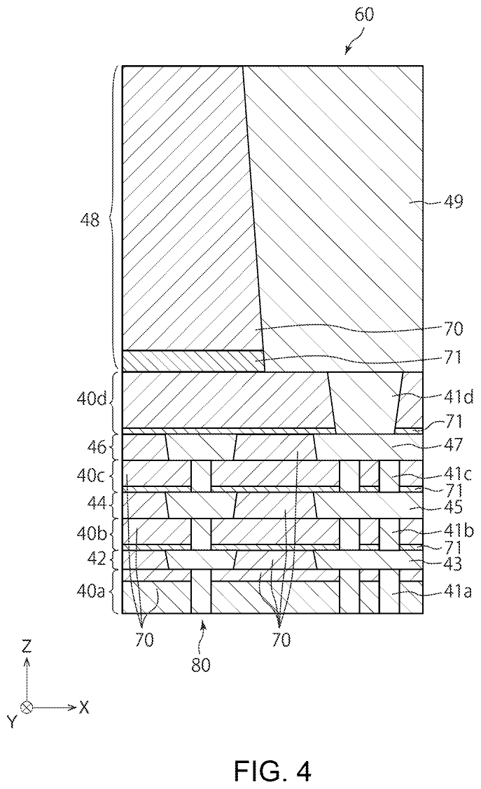

A configuration example of a semiconductor device 100 according to the present embodiment is described by way of FIGS. 1 to 4. FIG. 1 is a plan view of the semiconductor device 100 according to the present embodiment. FIG. 2 is a cross-sectional view thereof, taken along a line A-A in FIG. 1. FIG. 3 is a schematic diagram illustrating a chip ring 60 taken along a cross-section C-C in FIG. 2 in a three-dimensional manner. FIG. 4 is a cross-sectional view of the semiconductor device 100 taken along a line B-B in FIG. 1, which illustrates a detailed configuration example of a Cu multilayer wiring structure. As illustrated in FIGS. 1 to 4, the semiconductor device 100 according to the present embodiment includes a support substrate 10, an insulation layer (BOX: Buried oxide) 20, a semiconductor substrate 30, a plurality of interlayer dielectric films 40a to 40d, a plurality of plugs 41a to 41d, a plurality of wiring layers 42, 44, 46, and 48, a circuit element 50, and a chip ring 60. Further, FIGS. 1 and 4 also illustrate a part of an electrode wire 80 connected to the circuit element 50. The position of the part of the electrode wire 80 is schematically represented with the straight line in FIG. 1. In FIG. 2, a nitride film 71 described later is omitted for the sake of simplicity of illustration. In the present embodiment, a plane parallel to the main surface of the support substrate 10 is assumed as an x-y plane. The direction perpendicular to this x-y plane is assumed as the z-direction, and the positive side in the z-direction is referred to as “the upper side” or “the upward direction”.

As illustrated in FIGS. 1 and 2, the support substrate 10, the insulation layer 20, and the semiconductor substrate 30 are formed in, for example, an SOI (Silicon On Insulator) substrate. The insulation layer 20 is formed on the upper side of the support substrate 10, and the semiconductor substrate 30 is formed on the upper side of the insulation layer 20.

The semiconductor substrate 30 is, for example, a silicon substrate. The circuit element 50 is formed on the upper surface of the semiconductor substrate 30 and is, for example, a logic circuit element or an analog circuit element. The circuit element 50 according to the present embodiment includes, for example, at least one switching element as described later. The interlayer dielectric films 40a to 40d, the plugs 41a to 41d, the wiring layers 42, 44, 46, and 48, and the chip ring 60 form a Cu multilayer wiring structure. Wires 43, 45, 47, and 49 are formed in the wiring layers 42, 44, 46, and 48, respectively.

As illustrated in FIG. 3, the chip ring 60 is configured to extend discontinuously along the x-y plane, for example. A part of one string of the chip ring 60 is schematically illustrated in FIG. 3. This chip ring 60 is formed as integrated structures 602 in which the plugs 41a to 41d and the wires 43, 45, 47, and 49 are continuously connected to each other in the z-direction. Meanwhile, the chip ring 60 is discontinuous in its extending direction along the x-y plane.

The chip ring 60 according to the present embodiment has a function of preventing generation of a crack caused by mechanical shock at the time of dicing in the interlayer dielectric films 40a to 40d and the wiring layers 42, 44, 46, and 48 and separation of any of these films and wiring layers. Further, the chip ring 60 may be used as a marker for recognition of a chip periphery in automatic visual inspection, for example. The chip ring 60 according to the present embodiment corresponds to an element protection member.

As illustrated in FIG. 3, a length d602 of the integrated structure 602 of the chip ring 60 extending along the x-y plane can be set within a range of, for example, 30 to 300 μm. The chip ring 60 must have various fragmentation forms because properties of a crack generated in a semiconductor wafer with the semiconductor device 100 formed thereon are changed depending on the type of a blade used for dicing of the 20 semiconductor wafer. Further, even when the specification required for the semiconductor device 100 is changed depending on an envelope, the semiconductor device 100 according to the present embodiment allows adjustment of the length d602 of the integrated structure 602 of the chip 25 ring 60 and selection of the shape of the chip ring 60 in accordance with the circumstances. Furthermore, the intervals between the integrated structures 602 in the extending direction (the y-direction) can be adjusted depending on the specification required for the semiconductor device 100, as with the length d602 of each integrated structure 602.

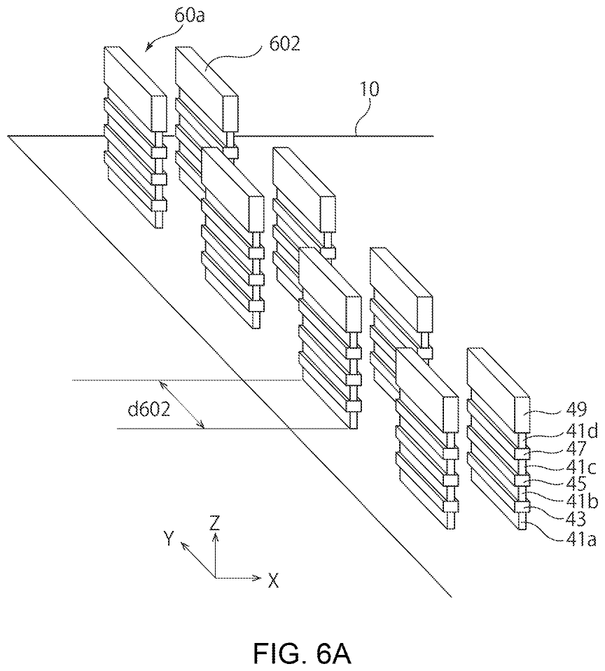

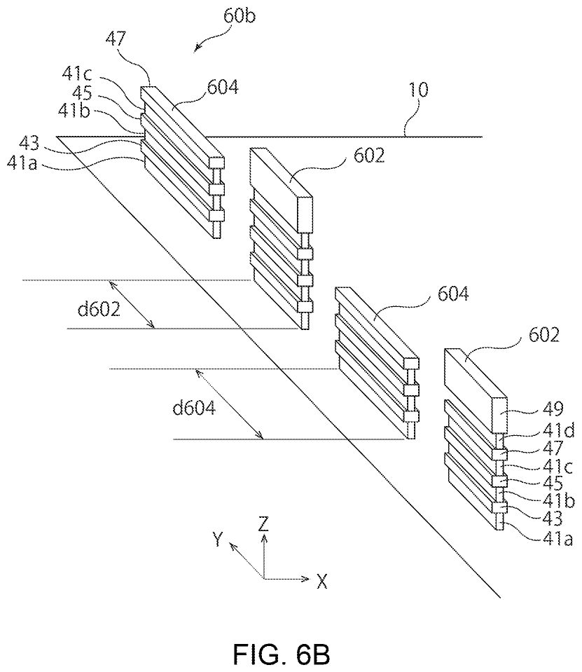

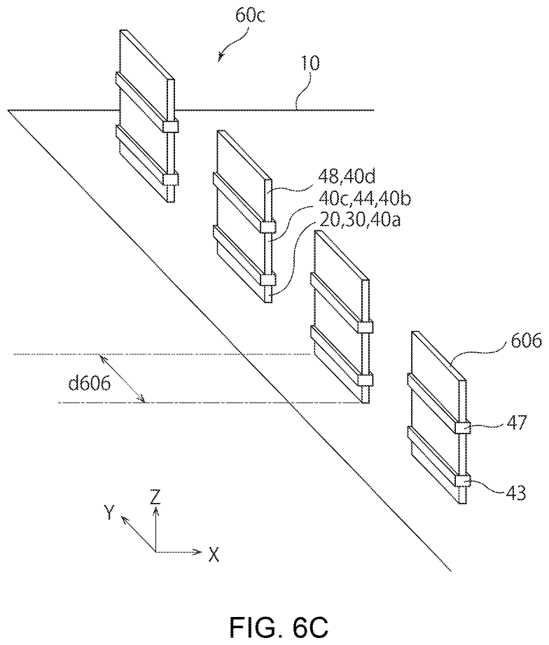

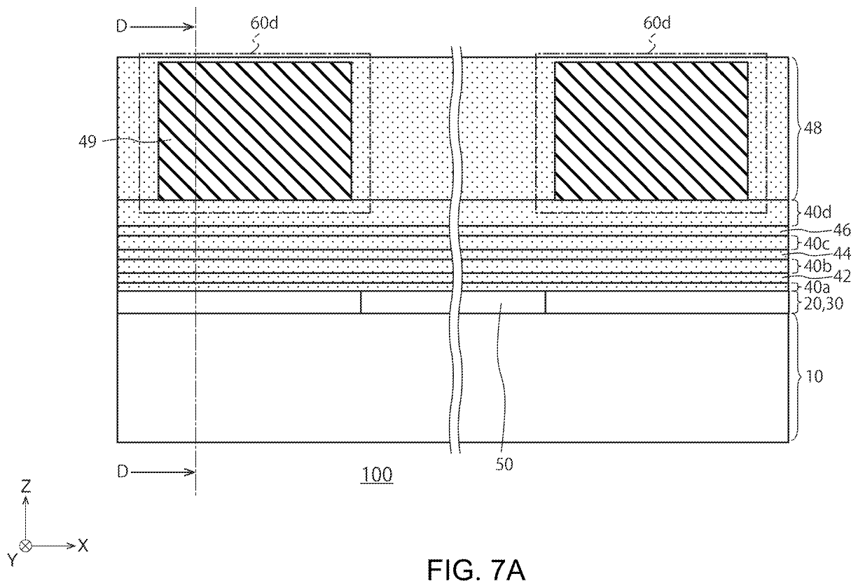

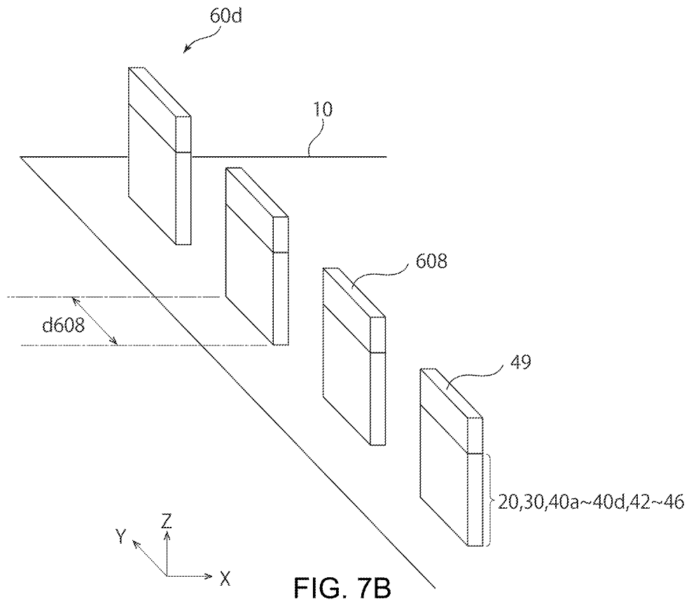

The plugs 41a to 41d according to the present embodiment each correspond to a first member, and the wires 43, 45, 47, and 49 each correspond to a second member. The chip ring 60 according to the present embodiment is configured by the plugs 41a to 41d and the wires 43, 45, 47, and 49, but the configuration thereof is not limited thereto. For example, a chip ring may be configured by the wires 43 and 47 as described as a chip ring 60b (see FIG. 6B) described later, or by the uppermost wire 49 only as described as a chip ring 60d (see FIG. 7A).

As described above, n interlayer dielectric films and n wiring layers are alternatively arranged above the semiconductor substrate 10, where n is an integer of 1 or more. In the present embodiment, n=4, for example. The chip ring 60 according to the present embodiment is configured by a conductive member that extends in at least any of the n interlayer dielectric films (for example, the interlayer dielectric films 40a to 40d) and the n wiring layers (for example, the wiring layers 42 to 48) along the upper surface (the x-y plane) of the semiconductor substrate 10 and discontinuously surrounds the circuit element 50 along the upper surface (the x-y plane) of the semiconductor substrate 10. The chip ring 60 according to the present embodiment can be formed in only any of the n interlayer dielectric films (for example, the interlayer dielectric films 40a to 40d) or only any of the n wiring layers (for example, the wiring layers 42 to 48).

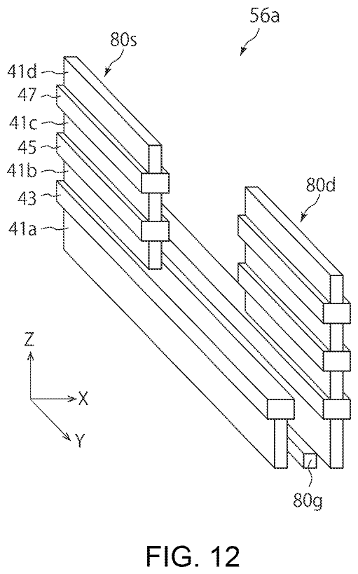

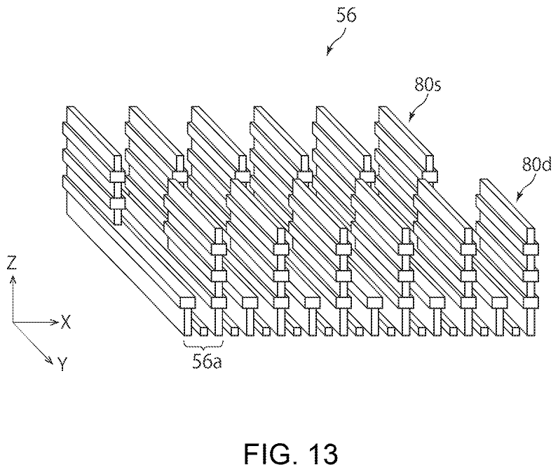

As illustrated in FIG. 4, the electrode wire 80 is electrically connected to the circuit element 50. The electrode wire 80 is configured by the plugs 41a to 41c and the wires 43, 45, and 47 that are connected to each other in the z-direction as an integrated structure continuous in the z-direction, for example. As described above, the chip ring 60 and the electrode wire 80 are formed by equivalent materials. The chip ring 60 and the electrode wire 80 can thus be formed by the same manufacturing process. A three-dimensional configuration example of the electrode wire 80 will be described later by way of FIGS. 12 and 13, for example.

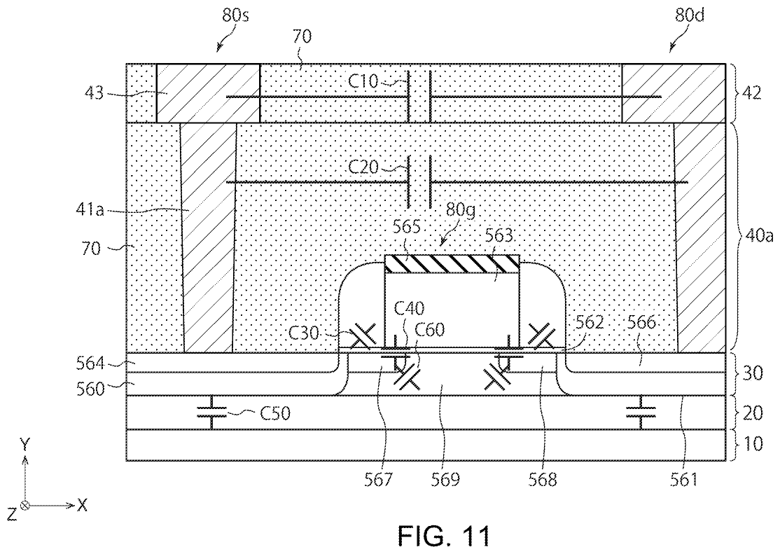

In more detail, as illustrated in FIG. 4, the first interlayer dielectric film 40a, the first plug 41a, and the first wiring layer 42 are provided in a level one above the semiconductor substrate 30 (see FIG. 2). The first interlayer dielectric film 40a is formed by, for example, an oxide insulation film with a dielectric constant of 3.5 or more. For example, an oxide insulation film 70 with a dielectric constant of 4.1 is used as the first interlayer dielectric film 40a. Although the first interlayer dielectric film 40a is formed by a two-layer structure of the oxide insulation film 70, it may be formed by a single layer. For example, the oxide insulation film 70 on the semiconductor substrate 30 side, which is one layer of the two-layer structure, includes a structure of a part of the circuit element 50 (for example, see FIG. 11 described later), and the oxide insulation film 70 that is the other layer does not include the circuit element 50. The oxide insulation film 70 is, for example, a film of silicon oxide. That is, the oxide insulation film 70 is a film of silicon monoxide (SiO), silicon dioxide (SiO₂), or the like and is moisture-resistant.

The first plug 41a is made of a conductive material such as W (tungsten). The first plug 41a is provided to penetrate through the first interlayer dielectric film 40a.

In the first wiring layer 42, the first-layer wire 43 is formed in accordance with a wiring pattern. The first-layer wire 43 is made of a conductive material such as Cu (copper). An insulation film between the first-layer wires 43 in the first wiring layer 42 is formed by an oxide insulation film with a dielectric constant of 3.5 or more. For example, the oxide insulation film 70 with a dielectric constant of 4.1 is used as the insulation film between the first-layer wires 43. With this configuration, the first plug 41a of the electrode wire 80 is electrically connected to the first wiring layer 42 and the circuit element 50 (see FIG. 2). The oxide insulation film 70 in the first wiring layer 42 according to the present embodiment corresponds to a first-wire insulation film.

Similarly, the second interlayer dielectric film 40b, the second plug 41b, and the second wiring layer 44 are provided in a level one above the first wiring layer 42. The second interlayer dielectric film 40b includes, for example, the oxide insulation film 70 and the nitride film 71. For example, the oxide insulation film 70 is formed on the upper side of the nitride film 71. The oxide insulation film 70 in the second wiring layer 44 according to the present embodiment corresponds to a second-wire insulation film. The nitride film 71 is, for example, a silicon nitride film Si₃N₄ and is moisture-resistant. The nitride film 71 is used as a stopper layer in etching, for example.

The second plug 41b is made of a conductive material such as Cu (copper). The second plug 41b is provided to penetrate through the second interlayer dielectric film 40b. In the second wiring layer 44, the second-layer wire 45 is formed in accordance with a wiring pattern. The second-layer wire 45 is made of a conductive material such as Cu (copper). The oxide insulation film 70 is formed between the second-layer wires 45. With this configuration, the second plug 41b electrically connects the first-layer wire 43 and the second-layer wire 45.

Similarly, the third interlayer dielectric film 40c, the third plug 41c, and the third wiring layer 46 are provided in a level one above the second wiring layer 44. The third interlayer dielectric film 40c includes, for example, the oxide insulation film 70 and the nitride film 71. For example, the oxide insulation film 70 is formed on the upper side of the nitride film 71.

The third plug 41c is made of a conductive material such as Cu (copper). The third plug 41c is provided to penetrate through the third interlayer dielectric film 40c. In the third wiring layer 46, the third-layer wire 47 is formed in accordance with a wiring pattern. The third-layer wire 47 is made of a conductive material such as Cu (copper). The oxide insulation film 70 is formed between the third-layer wires 47. With this configuration, the third plug 41c electrically connects the second-layer wire 45 and the third-layer wire 47.

Meanwhile, the chip ring 60 also has a connection structure equivalent to the electrode wire 80 from the first interlayer dielectric film 40a to the third wiring layer 46. In a level one above the third wiring layer 46, the fourth interlayer dielectric film 40d, the fourth plug 41d, and the fourth wiring layer 48 are provided. The fourth interlayer dielectric film 40d includes, for example, the oxide insulation film 70 and the nitride film 71. The oxide insulation film 70 is formed on the upper side of the nitride film 71.

The fourth plug 41d is made of a conductive material such as Cu (copper). The fourth plug 41d is provided to penetrate through the fourth interlayer dielectric film 40d. In the fourth wiring layer 48, the fourth-layer wire 49 is formed in accordance with a wiring pattern. The fourth-layer wire 49 is made of a conductive material such as Cu (copper). Between the fourth-layer wires 49, the oxide insulation film 70 and the nitride film 71 are formed in such a manner that the oxide insulation film 70 is located on the upper side of the nitride film 71. As described above, the chip ring 60 is configured by the plugs 41a to 41d and the wires 43, 45, 47, and 49 as an integrated structure. As for the plugs according to the present embodiment, the plug 41a is made of W (tungsten), and the plugs 41a to 41d are made of Cu (copper). In addition, a wiring layer can be formed on the fourth-layer wire 49 that is the uppermost layer. Alternatively, an insulation film can be formed on the fourth-layer wire 49. That is, a configuration preventing a wire from coming into direct contact with the atmosphere can be adopted.

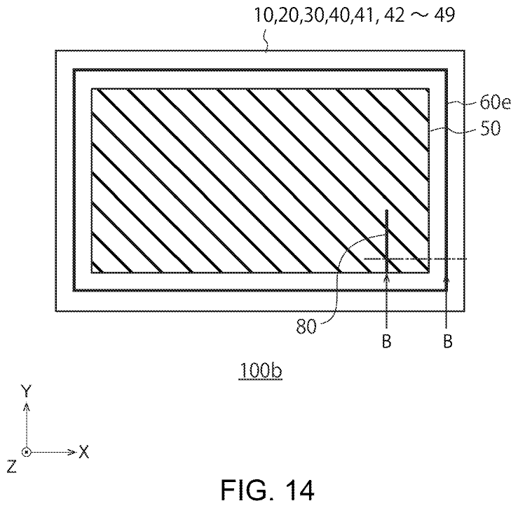

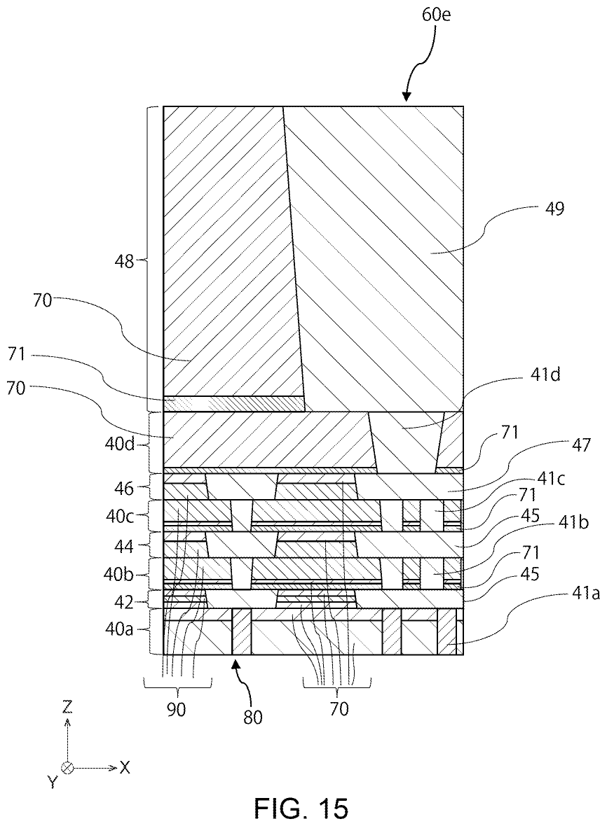

Referring back to FIGS. 1 and 2, a region of the semiconductor device 100, which is in contact with the atmosphere, is made of a highly moisture-resistant material. More specifically, whereas a low dielectric constant (low-k) material such as an FSG (fluorinated silicate glass) film with a dielectric constant of 3.4 (see FIGS. 14 and 15 described later) is used as an insulation film between wires in commonly used Cu wiring, the semiconductor device 100 according to the present embodiment uses the oxide insulation film 70 with a dielectric constant of 3.5 or more as an insulation film between wires in Cu wiring. Therefore, the influence of moisture absorption is suppressed in the cross-section of the semiconductor device 100 even when dicing is performed along, for example, the outer periphery of the support substrate 10. Accordingly, it is not necessary to form a chip ring continuous along the x-y plane (see FIGS. 14 and 15 described later) for waterproofing, in general.

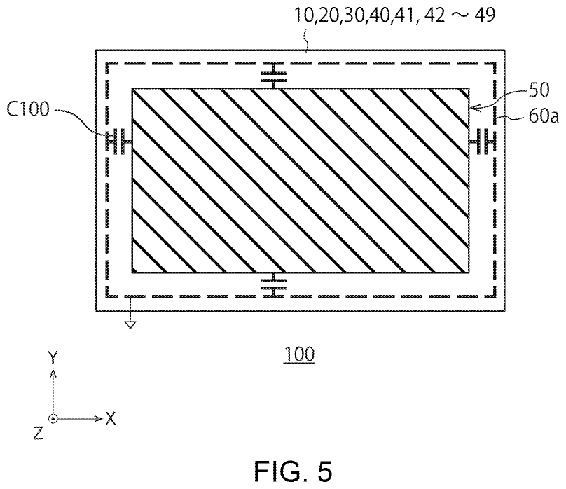

FIG. 5 is a diagram schematically illustrating capacitive coupling C100 between the chip ring 60 and the circuit element 50. Since the chip ring 60 is formed discontinuously, the capacitive coupling C100 with the circuit element 50 is reduced. In this case, as the length d602 of the integrated structure in the chip ring 60 is shorter, the capacitive coupling C100 can be reduced more. As described above, by making the chip ring 60 that is not necessary for waterproofing discontinuous, damage caused by mechanical shock at the time of dicing is prevented, and at the same time the capacitive coupling with the circuit element 50 can be reduced.

FIG. 6A is a diagram illustrating an example of a chip ring 60a having a double structure in a three-dimensional manner. As illustrated in FIG. 6A, at least a region of the chip ring 60a includes a first structure string of the integrated structures 602 which extends along the upper surface (the x-y plane) of the semiconductor substrate 10 in the y-direction and a second structure string of the integrated structures 602 which extends in the y-direction. That is, at least a region of the chip ring 60a can be formed by the integrated structures 602 arranged along the x-y plane in strings extending in parallel as a double structure. In other words, a region of the chip ring 60a formed annularly can have a double structure.

For example, the chip ring 60a in a region where resistance to mechanical shock at the time of dicing is to be increased can be formed by the double structure. This configuration can increase the resistance to mechanical shock at the time of dicing. Further, since the chip ring 60a is formed discontinuously as described above, the capacitive coupling with the circuit element 50 is reduced also in a case of employing the double structure. For example, in a case where the circuit element 50 includes a switching element, an off capacitance (Coff) of the switching element is reduced.

FIG. 6B is a schematic diagram illustrating two types of integrated structures 602 and 604 in the chip ring 60b in a three-dimensional manner. FIG. 6B illustrates the chip ring 60b along the cross-section C-C in FIG. 2 in a three-dimensional manner, similarly to FIG. 4. The integrated structure 604 is configured by the plugs 41a to 41c and the wires 43, 45, and 47. A length d604 of the integrated structure 604 extending along the x-y plane is longer than the length d602 of the integrated structure 602. The length d604 of the integrated structure 604 in its extending direction along the x-y plane and the length of the integrated structure 604 in the z-direction can be made different from each other. In this case, the capacitive coupling C100 with the circuit element 50 (see FIG. 5) can be adjusted by the length d604 and the length in the z-direction of the integrated structure 604.

FIG. 6C is a schematic diagram illustrating a structure 606 in a chip ring 60c in a three-dimensional manner. FIG. 6C is a schematic diagram illustrating the chip ring 60c along the cross-section C-C in FIG. 2 in a three-dimensional manner, similarly to FIG. 4. The integrated structure 606 is configured by the wires 43 and 47. The integrated structure 606 does not include the plugs 41a to 41d and the wires 45 and 49. In the interlayer dielectric films 40a to 40d and the wiring layers 44 and 48 in the z-direction in the structure 606, the oxide insulation film 70 and the nitride film 71 (see FIG. 4) are formed. In a case where the length d602 of the integrated structure in the chip ring 60 illustrated in FIG. 3 and a length d606 of the structure 606 are the same as each other, the length in the z-direction of a conductive member (the wire 43 or 47) in the structure 606 becomes short, so that the capacitive coupling with the circuit element 50 can be further reduced. As described above, when the influence of mechanical shock at the time of dicing on the damage is smaller, the capacitive coupling with the circuit element 50 can be further reduced by forming the chip ring 60c in only the specific wiring layers 42 and 46.

FIG. 7A is a cross-sectional view of an example of a chip ring 60d formed in the fourth wiring layer 48 that is the uppermost layer. FIG. 7B is a diagram schematically illustrating the structure 606 of the chip ring 60d in a three-dimensional manner. FIG. 7B is a schematic diagram illustrating the chip ring 60d along the cross-section C-C in FIG. 2 in a three-dimensional manner, similarly to FIG. 4. As illustrated in FIGS. 7A and 7B, in a case of prioritizing a marker function in functions of the chip ring 60d, which uses the chip ring 60d for alignment in a lithography process, for example, the chip ring 60d can be formed discontinuously only in the uppermost fourth wiring layer 48. In this case, the plugs 41a to 41d and the wires 43, 45, and 47 are not present below the wire 49 configuring the chip ring 60d. The oxide insulation film 70 and the nitride film 71 (see FIG. 4) are formed in the interlayer dielectric films 40a to 40d and the wiring layers 42, 44, and 46 in the z-direction in the structure 606.

In a case where the length d602 of the integrated structure 602 of the chip ring 60 illustrated in FIG. 3 and the length d606 of the structure 606 are the same as each other, the length in the z-direction of a conductive member (the wire 49) in the structure 606 becomes short, so that the capacitive coupling with the circuit element 50 can be further reduced. Also in this case, the damage caused by mechanical shock at the time of dicing can be prevented. In a case where the influence of mechanical shock at the time of dicing on the damage is smaller, forming the chip ring 60d only in the uppermost fourth wiring layer 48 makes it possible to further reduce the capacitive coupling with the circuit element 50 and to maintain the function as a marker used for alignment in a lithography process, for example.

As described above, according to the present embodiment, an insulation film in the semiconductor device 100 is formed by the moisture-resistant oxide insulation film 70 with a dielectric constant of 3.5 or more and the moisture-resistant nitride film 71, and the chip ring 60 surrounding the circuit element 50 is formed discontinuously. Accordingly, the capacitive coupling with the circuit element 50 can be reduced, and the shape, the arrangement, and the intervals of the integrated structures 602, 604, 606, and 608 included in the chip rings 60, 60a, 60b, 60c, and 60d can be arbitrarily designed and set. It is thus possible to reduce the capacitive coupling with the circuit element 50 while preventing the damage of the semiconductor device 100 caused by mechanical shock. Further, in a case where the circuit element 50 includes a switching element, it is possible to reduce an off capacitance (Coff) of the circuit element 50 while preventing the damage of the semiconductor device 100 caused by mechanical shock.

### Second Embodiment

A semiconductor device 100a according to a second embodiment is different from the semiconductor device 100 according to the first embodiment in including a plurality of first element regions 52 having a switching element and a second element region 54 controlling the switching element and in being configured as a high frequency switch. Differences from the semiconductor device 100 according to the first embodiment are explained below.

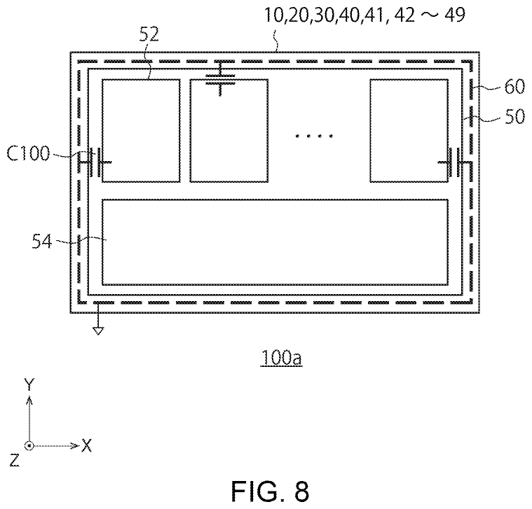

FIG. 8 is a plan view illustrating a configuration example of the semiconductor device 100a according to the second embodiment. As illustrated in FIG. 8, the circuit element 50 includes the first element regions 52 having a switching element and the second element region 54 controlling the switching element of the first element regions 52. Further, FIG. 8 schematically illustrates a coupling capacitance C100 between the chip ring 60 and a switching element 56. The switching element 56 according to the present embodiment is, for example, a field effect transistor (FET).

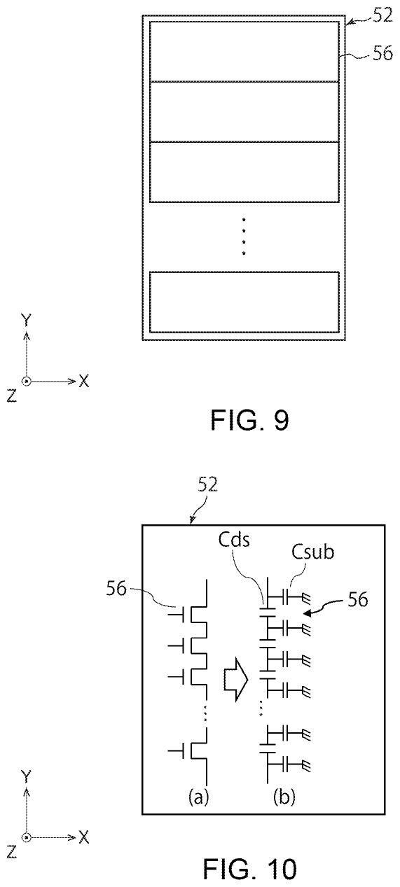

FIG. 9 is a diagram illustrating a detailed configuration example of the first element region 52. As illustrated in FIG. 9, the multi-finger switching elements 56 arranged in the y-direction vertically for obtaining a high breakdown voltage is arranged in the first element region 52, for example. FIG. 10 is a diagram illustrating a network in the off capacitance (Coff) when the switching elements 56 illustrated in FIG. 9 are off. FIG. 10(a) is a diagram of the multi-finger switching elements 56 arranged in the y-direction vertically with symbols for circuit diagram, and FIG. 10(b) illustrates an equivalent circuit illustrating source-drain capacitances Cds and coupling capacitances Csub with a chip ring when the switching elements 56 are off. The switching element 56 in an off state has the source-drain capacitance Cds and the coupling capacitance Csub with the chip ring as illustrated in the drawing.

A detailed configuration example of the switching element 56 is described by way of FIGS. 11 to 13. FIG. 11 is a schematic cross-sectional view of a switching element 56a according to the present embodiment at the level of the first-layer wire 43 and the lower levels. FIG. 12 is a diagram illustrating a Cu multilayer wiring structure of the switching element 56a forming the switching element 56 in a three-dimensional manner. FIG. 13 is a diagram illustrating a Cu multilayer wiring structure of the switching element 56 having a multi-finger structure in the first element region 52 in a three-dimensional manner. As illustrated in FIGS. 11 to 13, the switching element 56 is configured by the switching elements 56a connected in parallel.

As illustrated in FIG. 11, the switching element 56a is, for example, an n-channel transistor. In the following description, n+ means that the conductivity type is N type and the impurity concentration is high enough to form a silicide layer. In this n-channel transistor, an n-type LDD (Lightly Doped Drain) region 567 is formed which is the same type as an n+ layer 560, for example. The LDD region 567 is formed to have an impurity concentration lower than that of the n+ layer 560. Further, an n+ layer 561 and an n-type LDD region 568 are formed. A gate electrode 80g has a polysilicon layer 563 and a silicide layer 565. That is, the silicon layer 563 is formed above a p-well 569 via a gate oxide insulation film 562, and the silicide layer 565 is formed on the silicon layer 563.

The first plug 41a on the source electrode wire 80s side is connected to the upper portion of the n+ layer 560 via a silicide layer 564. Further, the first plug 41a on the drain electrode wire 80d side is connected to the upper portion of the n+ layer 561 via a silicide layer 566. The silicide layer 564 and the silicide layer 566 according to the present embodiment correspond to a first region and a second region, respectively. Further, the first-layer wire 43 according to the present embodiment connected to the electrode layer 564 corresponds to a first-region wire, and the first-layer wire 43 connected to the electrode layer 566 corresponds to a second-region wire.

A high frequency switch is built into the front end of a mobile communication terminal such as a mobile phone and turns on and off a high frequency (RF). An important characteristic of such a high frequency switch is to reduce loss of a high frequency passing therethrough. Therefore, it is important to reduce the resistance of an FET in an on state (the on resistance) or the capacitance of the FET in an off state (the off capacitance). That is, it is important to make the product (Ron*Coff) of the on resistance and the off capacitance (Coff) smaller.

The off capacitance (Coff) has a component generated in a diffusion layer, a substrate, and the like (an intrinsic component) and a component generated in a gate electrode, a contact plug, and a wire on or above them (an extrinsic component). As illustrated in FIG. 11, with this configuration, examples of the extrinsic component of the switching element 56 include wiring capacitances C10 and C20 and the coupling capacitance C100 between the chip ring 60 and the switching element 56 (see FIG. 8). The wiring capacitance C10 is a wiring capacitance between the first-layer wires 43, and the wiring capacitance C20 is a wiring capacitance between the plugs 41a. Examples of the intrinsic component include capacitances C30, C40, C50, and C60. The capacitance C30 is a capacitance between the gate oxide insulation film 562 and the silicon layer 563, and the capacitances C40 are capacitances between the silicon layer 563 and the LDD regions 567 and 568. Similarly, the capacitance C50 is a capacitance between the support substrate 10 and the semiconductor substrate 30, and the capacitances C60 are capacitances between the LDD regions 567 and 568 and the p-well 569.

The semiconductor device 100a according to the present embodiment uses an SOI substrate and therefore makes the capacitance C50 related to the intrinsic component smaller than in a case of using a bulk substrate. Therefore, further reduction of capacitances other than the capacitance C50, in particular, the wiring capacitances C10 and C20 and an earth capacitance is important for reducing the off capacitance (Coff). For example, the wiring capacitances C10 and C20 are capacitances between the source electrode wire 80s and the drain electrode wire 80d illustrated in FIG. 12 described later and may reach about 30% of the entire source-drain capacitance because the capacitance C50 is small. Meanwhile, as for the earth capacitance, it is important to reduce the coupling capacitance C100 between the chip ring 60 and the switching element 56 (see FIG. 8).

As illustrated in FIG. 12, the Cu multilayer wiring structure of the switching element 56a includes the source electrode wire 80s connected to a source region, the drain electrode wire 80d connected to a drain region, and the gate electrode 80g.

In the source electrode wire 80s, the plug 41a connected to the source region, the first-layer wire 43, the plug 41b, the second-layer wire 45, the plug 41c, the third-layer wire 47, and the plug 41d are connected in an integrated manner, for example. Similarly, in the drain electrode wire 80d, the plug 41a connected to the drain region, the first-layer wire 43, the plug 41b, the second-layer wire 45, the plug 41c, the third-layer wire 47, and the plug 41d are connected in an integrated manner, for example.

In more detail, the first-layer wire 43 in the first wiring layer 42, connected to the source region (see FIG. 2), and the other first-layer wire 43 in the first wiring layer 42, connected to the drain region, are arranged in the y-direction (the first direction) and are opposed to each other in the first wiring layer 42 in the x-direction (the second direction) perpendicular to the y-direction (the first direction).

Further, the second-layer wire 45 in the second wiring layer 44, connected to the source region (see FIG. 2), and the other second-layer wire 45 in the second wiring layer 44, connected to the drain region, are arranged in the y-direction (the first direction) and are not opposed to each other in the x-direction (the second direction) perpendicular to the y-direction (the first direction). Accordingly, the interlayer capacitance between the second-layer wire 45 in the second wiring layer 44 and the other second-layer wire 45 in the second wiring layer 44 is reduced. Similarly, the interlayer capacitance between the third-layer wire 47 in the third wiring layer 46 (see FIG. 2) and the other third-layer wire 47 in the third wiring layer 46 is reduced.

With reference to FIGS. 2 and 12 and as illustrated in FIG. 13, the switching element 56 is a so-called multi-finger type. The switching element 56 is configured by the elements 56a connected in parallel, as described above.

Between the second-layer wires 45 adjacent to each other in the x-direction in the second wiring layer 44, the distance in the x-direction becomes longer and the interlayer capacitance is reduced. Similarly, between the third-layer wires 47 adjacent to each other in the x-direction in the third wiring layer 46, the distance in the x-direction becomes longer and the interlayer capacitance is reduced. As is apparent from these facts, in the switching element 56 according to the present embodiment, integrated structures of the plug 41b, the second-layer wire 45, the plug 41c, the third-layer wire 47, and the plug 41d are formed not to be opposed to each other in the x-direction. Accordingly, increase in the wiring capacitances C10 and C20 (see FIG. 11) and the like, which are extrinsic components, can be suppressed even when an oxide insulation film with a dielectric constant of 3.5 or more, for example, is used for a Cu multilayer wiring structure. That is, even when the oxide insulation film 70 with a dielectric constant of 3.5 or more is used as an insulation film in the second wiring layer 44 and the third wiring layer 46, the wiring capacity of the switching element 56 is hardly increased.

As described above, the wiring capacity between the source and the drain becomes small in the interlayer dielectric films 40b to 40c, the second wiring layer 44, the third wiring layer 46, and the fourth wiring layer 48 above the first wiring layer 42. Therefore, in the switching element 56 according to the present embodiment, the source-drain wiring capacity is generated mainly in the first wiring layer 42.

FIG. 14 is a plan view of a semiconductor device 100b according to a comparative example. The semiconductor device 100b according to the comparative example has a general Cu multilayer wiring structure. In a Cu multilayer wiring structure, an FSG (fluorinated silicate glass) film with a dielectric constant of 3.4 is used as a main component in general.

As illustrated in FIG. 14, a chip ring 60e in the semiconductor device 100b according to the comparative example is different from the chip ring 60 in the semiconductor device 100 according to the present embodiment in being formed continuously in its extending direction along the x-y plane. The chip ring 60e is continuously formed, thereby waterproofing the FSG (fluorinated silicate glass) film.

FIG. 15 is a cross-sectional view of the semiconductor device 100b, taken along a line B-B in FIG. 14. As illustrated in FIG. 15, an FSG (fluorinated silicate glass) film 90 with a dielectric constant of 3.4, which is a low-k material with a low dielectric constant, is used as insulation films between the wires 43, 45, and 47 in the wiring layers 42, 44, and 46 and as the interlayer dielectric films 40b and 40c in the semiconductor device 100b according to the comparative example as described above. Since the FSG (fluorinated silicate glass) film 90 is less moisture-resistant, the chip ring 60e (see FIG. 14) is formed continuously along the x-y plane, as described above.

FIG. 15 is a diagram illustrating a typical configuration example of the arrangement of the FSG films 90 in each layer in a 130-nm node process. The FSG film 90 occupies a large part (at least half) between wires in the wiring layer 44 or 46. However, as described above, the percentage of the FSG film 90 is small in the first wiring layer 42 that accounts for a large part of the capacitance of a high frequency switch. The percentage of the FSG film 90 in the first wiring layer 42 is typically half or less. This is because formation of the first plug 41a made of W (tungsten) via the FSG film 90 is difficult.

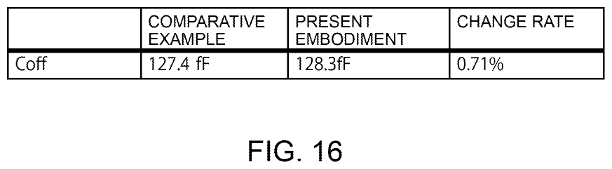

FIG. 16 is a table representing the off capacitance Coff of the semiconductor device 100b according to the comparative example (FIGS. 14 and 15) and the off capacitance Coff of the semiconductor device 100 according to the present embodiment (FIGS. 1 to 4) in a case where the chip ring 60 is formed continuously. That is, these off capacitances (Coff) are examples obtained for continuous chip rings. The rate of change is 0.71 percent.

For example, the dielectric constant of the FSG film 90, which is a typical low-k material, is 3.4 and is smaller than the dielectric constant of the oxide insulation film 70, 4.1, by about 20%. Although the wiring capacity in a general LSI is reduced in accordance with the dielectric constant, the influence of the oxide insulation film 70 with a dielectric constant of 4.1 is limited in a case of a high frequency switch. This is because, since the thick FSG film 90 (for example, with a thickness of about 100 nm) cannot be used for the first-layer wire 43 occupying a large part of the capacitance of the high frequency switch as described above, the effect of use of the low-k material is small. Therefore, in a case where the chip ring of the semiconductor device 100 according to the present embodiment (FIGS. 1 to 4) is formed to be continuous by using the oxide insulation film 70 instead of the low-k material, increase of the capacitance of the high frequency switch is suppressed to about 0.71 percent despite increase in the dielectric constant.

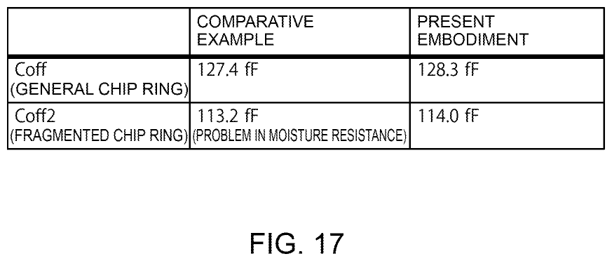

FIG. 17 represents the off capacitance Coff of the semiconductor device 100b according to the comparative example and the off capacitance Coff of the semiconductor device 100 according to the present embodiment. The upper row corresponds to a case where the chip ring 60e (see FIG. 14) is formed continuously. The lower row corresponds to a case where the chip ring 60 (see FIG. 8) is formed discontinuously. As is apparent from this table, fragmentation of the chip ring reduces the off capacitance Coff by about 10%. As represented in FIG. 17, although the permittivity between the first-layer wires 43 increases in the semiconductor device 100 according to the present embodiment, the chip ring can be formed discontinuously, and the off capacitance Coff can be reduced as a whole.

As described above, in the switching element 56 of the semiconductor device 100a according to the present embodiment, integrated structures of the plug 41b, the second-layer wire 45, the plug 41c, the third-layer wire 47, and the plug 41d are formed not to be opposed. Therefore, increase in the off capacitance (Coff) can be suppressed even when the oxide insulation film 71 having a dielectric constant higher than that of a low-k material for an insulation film in a Cu multilayer wiring structure. For this reason, the Cu multilayer wiring structure can be formed without using the FSG (fluorinated silicate glass) film 90 that is a low-k material, so that moisture resistance can be increased. As a result, the chip ring 60 can be formed discontinuously, and therefore the coupling capacitance C100 (see FIG. 8) between the chip ring 60 and the switching element 56, which may cause increase in the off capacitance (Coff), can be reduced.

Further, in the semiconductor device 100a according to the present embodiment, the support substrate 10, the insulation layer 20, and the semiconductor substrate 30 are formed in an SOI (Silicon On Insulator) substrate, and the internal capacitance C50 can be made further smaller. Thus, although the internal capacitance C50 becomes small in the SOI substrate and the percentage of the wiring capacity in the overall capacity becomes large, the wiring capacity does not largely increase in the present embodiment even if the dielectric constant of the insulation film increases, because the integrated structures of the plug 41b, the second-layer wire 45, the plug 41c, the third-layer wire 47, and the plug 41d are not opposed to each other in the x-direction. As described above, since the chip ring 60 formed to surround the circuit element 50 is discontinuous, the damage of the semiconductor device 100a caused by mechanical shock can be prevented, and at the same time both reduction of the entire capacitive coupling in the semiconductor device 100a and reduction of the internal capacitance C50 can be achieved.

### Third Embodiment

A semiconductor device 100c according to a third embodiment is different from the semiconductor device 100a according to the second embodiment in that the shapes of chip rings 60f and 60g are changed depending on the positions of the chip rings 60f and 60g. Differences from the semiconductor device 100a according to the second embodiment are explained below.

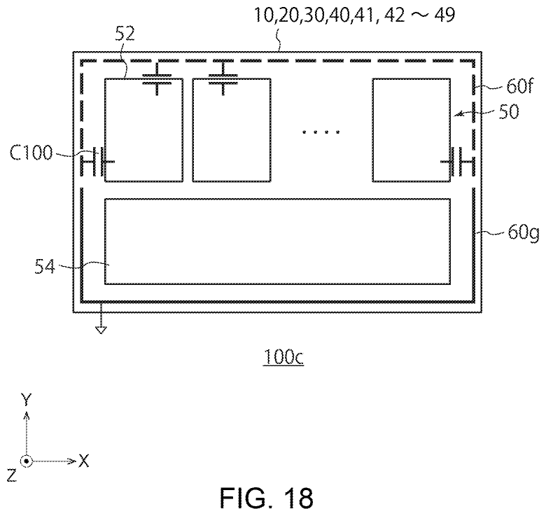

FIG. 18 is a plan view of the semiconductor device 100c according to the third embodiment. As illustrated in FIG. 18, the length of an integrated structure in each of the chip rings 60f and 60g along the x-y plane is changed depending on the position where the chip ring 60f or 60g is provided. The chip ring 60f is integrated in the z-direction and discontinuous in a direction along the x-y plane, similarly to the chip ring 60 illustrated in FIG. 3. Meanwhile, the chip ring 60g is integrated in the z-direction and continuous in the direction along the x-y plane.

More specifically, in the chip ring 60f formed next to the first element region 52, a first length of the discontinuous integrated structure along the x-y plane is set to be short. Meanwhile, in the chip ring 60g formed next to the second element region 54, a second length of the integrated structure along the x-y plane is set to be longer than the first length in the chip ring 60f. Accordingly, the coupling capacitance with the chip ring 60f can be reduced on the first element region 52 side, and the strength at the time of dicing on the second element region 54 side can be increased. Further, the chip ring 60g is electrically connected to the support substrate 10. The chip ring 60g can thus have a shielding effect. Meanwhile, the discontinuous integrated structures in the chip ring 60f are not electrically connected to the support substrate 10.

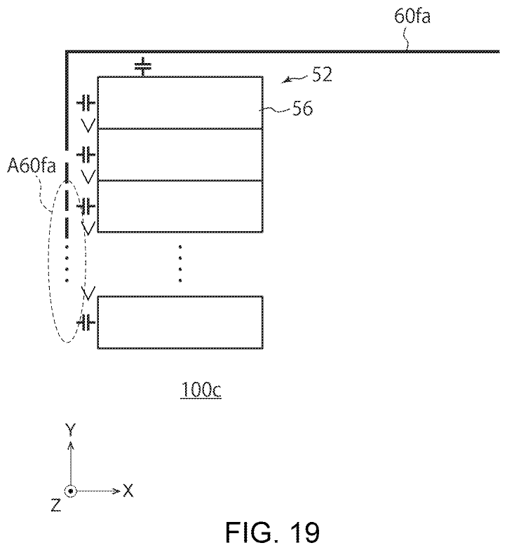

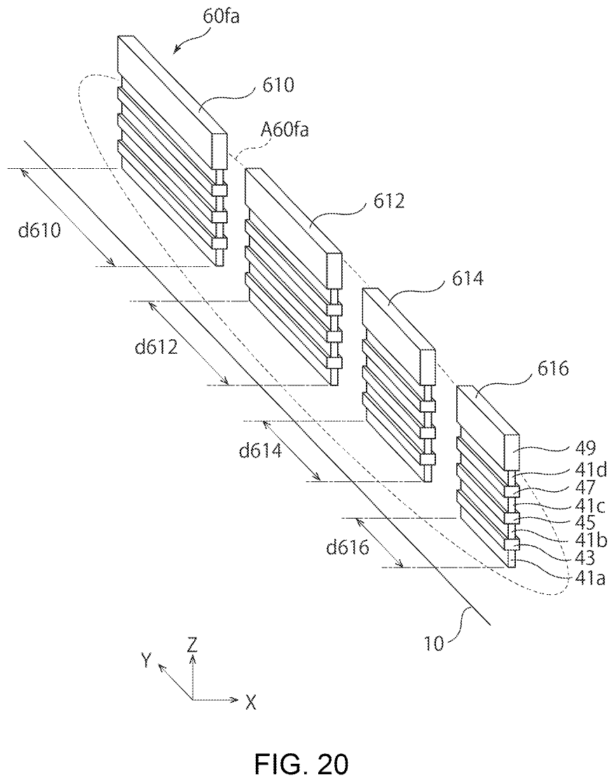

FIG. 19 is a plan view illustrating a part of the semiconductor device 100c according to the third embodiment. FIG. 20 is a diagram illustrating integrated structures 610, 612, 614, and 616 in a chip ring 60fa in a region A60f in FIG. 19 in a three-dimensional manner. As illustrated in FIGS. 19 and 20, the chip ring 60fa is provided in such a manner that the integrated structures have lengths d610, d612, d614, and d616 along the x-y plane. As is apparent from the drawings, the lengths of the integrated structures 610, 612, 614, and 616 become shorter as the number of stages of the switching elements 56 connected in multiple stages increases.

More specifically, the first element region 52 including the switching elements 56 has a multi-stage configuration in order to ensure a high breakdown voltage in an off state. That is, the switching elements 56 (see FIG. 10) are connected in series. In addition, the switching elements 56 are coupled in multiple stages to form a string along one direction (the y-direction) in an upper surface (the x-y plane) of the semiconductor substrate 10.

Therefore, unequal partial pressures may be generated in the stages, which cause breakdown of a stage to which a large partial pressure is applied and cause deterioration of a breakdown voltage. The phenomenon of unequal partial pressures is caused by the difference of the influence of an earth capacitance on the switching element 56 between the stages. Accordingly, in general, adjustment is performed to make the influence of the earth capacitance in each stage equal by adding the earth capacitance to the switching element 56 by using an MIM (Metal-Insulator-Metal) capacitor.

However, the area occupied by the added MIM capacitor is large, and therefore the chip area of the entire semiconductor device 100c becomes large. Meanwhile, since the semiconductor device 100c does not use a low-k material, the chip ring 60fa can be designed with high flexibility without considering the moisture resistance. Accordingly, in the semiconductor device 100c according to the present embodiment, the length of the fragmented chip ring 60fa is changed depending on the position of the switching element 56 in each stage, whereby the earth capacitances are adjusted to be equal to each other.

As illustrated in FIG. 20, a chip ring fragmented to have the integrated structure 610 with the longer length d610 is provided near the switching element 56 to which the earth capacitance is to be added. Meanwhile, a chip ring fragmented to have the integrated structure 616 with the shorter length d616 is provided near the switching element 56 to which the earth capacitance is not to be added. The earth capacitance for each switching element 56 can thus be adjusted. For example, in the order of the integrated structures 610, 612, 614, and 616, the earth capacitances for the associated switching elements 56 are reduced. Consequently, since the chip ring originally provided is used, an additional occupation area is not required, and the semiconductor device 100c can be downsized, as compared with adjustment using an MIM capacitor.

The embodiments include the following aspects.

(Note 1) A semiconductor device comprising:
a semiconductor substrate;
a circuit element formed on an upper surface side of the semiconductor substrate and including at least one switching element;
a first wiring layer including a plurality of first wires electrically connected to the circuit element, and provided above the semiconductor substrate via a first interlayer dielectric film; and
an element protection member extending along an upper surface of the semiconductor substrate to discontinuously surround the circuit element with a conductive member, wherein
a first wire insulation film between the first wires is formed by an oxide insulation film with a dielectric constant of 3.5 or more.
   (Note 2) The device of Note 1, wherein
n interlayer dielectric films and n wiring layers are alternately arranged above the semiconductor substrate, where n is an integer of 1 or more, and
the element protection member extends along the upper surface of the semiconductor substrate in at least any of the n interlayer dielectric films and the n wiring layers.
   (Note 3) The device of Note 2, wherein
the element protection member in at least any of the n interlayer dielectric films is a first member that is conductive, and the element protection member in at least any of the n wiring layers is a second member that is conductive, and
the first member and the second member that are vertically adjacent to each other in a direction perpendicular to the upper surface of the semiconductor substrate form an integrated structure, and a length of the integrated structure in a direction of discontinuous extension around the circuit element is different depending on a position where the integrated structure is provided.
   (Note 4) The device of Note 3, wherein
the circuit element includes a first element region including a plurality of the switching elements connected in series,
the switching elements are coupled in multiple stages to form a string along one direction in the upper surface of the semiconductor substrate, and
the length of the integrated structure extending along the one direction becomes shorter as the number of the stages of the switching elements coupled in multiple stages increases.
   (Note 5) The device of Note 3, wherein
the circuit element includes
a first element region including the switching element, and
a second element region configured to control the switching element,
the element protection member has a first element protection member formed next to the first element region and a second element protection member formed next to the second element region,
the integrated structure in the first element protection member has a first length in an extending direction of the first element protection member, and
the integrated structure in the second element protection member has a second length in an extending direction of the second element protection member, the second length being longer than the first length.
   (Note 6) The device of Note 3, wherein the element protection member is formed in only an uppermost layer of the n interlayer dielectric films and the n wiring layers.
   (Note 7) The device of any one of Notes 1 to 6, wherein
the semiconductor substrate is formed in an SOI substrate,
the device further includes a second wiring layer provided above the first wiring layer via a second interlayer dielectric film,
a first region wire in the second wiring layer, connected to a first region of the switching element, and a second region wire in the second wiring layer, connected to a second region of the switching element different from the first region, are arranged to extend in a first direction in parallel to each other and are not opposed to each other in the second wiring layer in a second direction perpendicular to the first direction, and
a second wire insulation film between a plurality of second wires in the second wiring layer is formed by an oxide insulation film with a dielectric constant of 3.5 or more.
   (Note 8) The device of Note 7, wherein
in the switching element, wires in the first wiring layer and the second wiring layer are Cu wires, and
a third region wire in the first wiring layer, connected to the first region, and a fourth region wire in the first wiring layer, connected to the second region, are arranged to extend in the first direction and are opposed to each other in the first wiring layer in the second direction.
   (Note 9) The device of Note 5, further comprising a support substrate formed in an SOI substrate together with the semiconductor substrate and configured to support the semiconductor substrate from below, wherein
the first element protection member is not electrically connected to the support substrate, and
the second element protection member is electrically connected to the support substrate.
   (Note 10) A high frequency switch comprising:
a semiconductor substrate;
a circuit element including a first element region that is formed on an upper surface side of the semiconductor substrate and includes a switching element and a second element region configured to control the switching element;
a first wiring layer including a plurality of first wires electrically connected to the circuit element and provided above the semiconductor substrate via a first interlayer dielectric film; and
an element protection member extending along an upper surface of the semiconductor substrate to discontinuously surround the circuit element with a conductive member, wherein
a first wire insulation film between the first wires is formed by an oxide insulation film with a dielectric constant of 3.5 or more.
   (Note 11) The device of Note 1, wherein
at least a region of the element protection member has a double structure including a third element protection member and a fourth element protection member,
the third element protection member is formed discontinuously by a conductive member to extend along the upper surface in a third direction, and
the fourth element protection member is formed discontinuously by a conductive member to extend along the upper surface in the third direction in parallel to the third element protection member.
   (Note 12) The device of Note 8, wherein
the first region wire and the third region wire form an integrated structure via a first member that is conductive in the second interlayer dielectric film, and
the second region wire and the fourth region wire form an integrated structure via the first member that is conductive in the second interlayer dielectric film.
   (Note 13) The device of Note 1, wherein the first wire insulation film is an oxide insulation film with a dielectric constant of 4.1 or more.
   (Note 14) The device of Note 7, wherein the second wire insulation film is an oxide insulation film with a dielectric constant of 4.1 or more.

While certain embodiments of the present invention have been described, these embodiments have been presented by way of example only, and are not intended to limit the scope of the inventions. Indeed, the novel embodiments described herein may be embodied in a variety of other forms and various omissions, substitutions, and changes may be made without departing from the spirit of the inventions. Such embodiments and modifications thereof are included in the spirit and scope of the invention and are also included in the scope of the inventions described in the claims and equivalents thereof.

1. A semiconductor device comprising:
a semiconductor substrate;
a circuit element formed on an upper surface side of the semiconductor substrate and including at least one switching element;
a first wiring layer including a plurality of first wires electrically connected to the circuit element, and provided above the semiconductor substrate via a first interlayer dielectric film; and
an element protection member extending along an upper surface of the semiconductor substrate to discontinuously surround the circuit element with a conductive member, wherein
a first wire insulation film between the first wires is formed by an oxide insulation film with a dielectric constant of 3.5 or more.

2. The device of claim 1, wherein
n interlayer dielectric films and n wiring layers are alternately arranged above the semiconductor substrate, where n is an integer of 1 or more, and
the element protection member extends along the upper surface of the semiconductor substrate in at least any of the n interlayer dielectric films and the n wiring layers.

3. The device of claim 2, wherein
the element protection member in at least any of the n interlayer dielectric films is a first member that is conductive, and the element protection member in at least any of the n wiring layers is a second member that is conductive, and
the first member and the second member that are vertically adjacent to each other in a direction perpendicular to the upper surface of the semiconductor substrate form an integrated structure, and a length of the integrated structure in a direction of discontinuous extension around the circuit element is different depending on a position where the integrated structure is provided.

4. The device of claim 3, wherein
the circuit element includes a first element region including a plurality of the switching elements connected in series,
the switching elements are coupled in multiple stages to form a string along one direction in the upper surface of the semiconductor substrate, and
the length of the integrated structure extending along the one direction becomes shorter as the number of the stages of the switching elements coupled in multiple stages increases.

5. The device of claim 3, wherein
the circuit element includes
a first element region including the switching element, and
a second element region configured to control the switching element,
the element protection member has a first element protection member formed next to the first element region and a second element protection member formed next to the second element region,
the integrated structure in the first element protection member has a first length in an extending direction of the first element protection member, and
the integrated structure in the second element protection member has a second length in an extending direction of the second element protection member, the second length being longer than the first length.

6. The device of claim 3, wherein the element protection member is formed in only an uppermost layer of the n interlayer dielectric films and the n wiring layers.

7. The device of claim 1, wherein
the semiconductor substrate is formed in an SOI substrate,
the device further includes a second wiring layer provided above the first wiring layer via a second interlayer dielectric film,
a first region wire in the second wiring layer, connected to a first region of the switching element, and a second region wire in the second wiring layer, connected to a second region of the switching element different from the first region, are arranged to extend in a first direction in parallel to each other and are not opposed to each other in the second wiring layer in a second direction perpendicular to the first direction, and
a second wire insulation film between a plurality of second wires in the second wiring layer is formed by an oxide insulation film with a dielectric constant of 3.5 or more.

8. The device of claim 7, wherein
in the switching element, wires in the first wiring layer and the second wiring layer are Cu wires, and
a third region wire in the first wiring layer, connected to the first region, and a fourth region wire in the first wiring layer, connected to the second region, are arranged to extend in the first direction and are opposed to each other in the first wiring layer in the second direction.

9. The device of claim 5, further comprising a support substrate formed in an SOI substrate together with the semiconductor substrate and configured to support the semiconductor substrate from below, wherein
the first element protection member is not electrically connected to the support substrate, and
the second element protection member is electrically connected to the support substrate.

10. The device of claim 1, wherein
at least a region of the element protection member has a double structure including a third element protection member and a fourth element protection member,
the third element protection member is formed discontinuously by a conductive member to extend along the upper surface in a third direction, and
the fourth element protection member is formed discontinuously by a conductive member to extend along the upper surface in the third direction in parallel to the third element protection member.

11. The device of claim 8, wherein
the first region wire and the third region wire form an integrated structure via a first member that is conductive in the second interlayer dielectric film, and
the second region wire and the fourth region wire form an integrated structure via the first member that is conductive in the second interlayer dielectric film.

12. The device of claim 1, wherein the first wire insulation film is an oxide insulation film with a dielectric constant of 4.1 or more.

13. The device of claim 7, wherein the second wire insulation film is an oxide insulation film with a dielectric constant of 4.1 or more.

14. A high frequency switch comprising:
a semiconductor substrate;
a circuit element including a first element region that is formed on an upper surface side of the semiconductor substrate and includes a switching element and a second element region configured to control the switching element;
a first wiring layer including a plurality of first wires electrically connected to the circuit element and provided above the semiconductor substrate via a first interlayer dielectric film; and
an element protection member extending along an upper surface of the semiconductor substrate to discontinuously surround the circuit element with a conductive member, wherein
a first wire insulation film between the first wires is formed by an oxide insulation film with a dielectric constant of 3.5 or more.
